(19) United States
(12) Patent Application Publication
(10) Pub. No.: US 2024/0429354 A1
(43) Pub. Date: Dec. 26, 2024

(54) SEMICONDUCTOR LIGHT-EMITTING APPARATUS

(71) Applicant: NIKKISO CO., LTD., Tokyo (JP)

(72) Inventors: Izumi KIDA, Ishikawa (JP); Naoki SHIBATA, Ishikawa (JP); Tetsuhiko INAZU, Ishikawa (JP)

(21) Appl. No.: 18/748,749

(22) Filed: Jun. 20, 2024

(30) Foreign Application Priority Data
Jun. 21, 2023 (JP) 2023-101370

(51) Int. Cl. H01L 33/58; H01L 33/48; H01L 33/62

(52) U.S. Cl. CPC H01L 33/58; H01L 33/486; H01L 33/62

(57) ABSTRACT

A semiconductor light-emitting apparatus includes: a package substrate; a semiconductor light-emitting element including an anode electrode and a cathode electrode bonded to the package substrate, a semiconductor layer on the anode electrode and the cathode electrode, and a translucent substrate on the semiconductor layer; and a covering member that is in contact with an upper surface of the translucent substrate, has a dome shape that is convex upward, has translucency at an emission wavelength of the semiconductor light-emitting element, has a lower refractive index than the translucent substrate, and that is not in contact with the package substrate.

### RELATED APPLICATION

Priority is claimed to Japanese Patent Application No. 2023-101370, filed on Jun. 21, 2023, the entire content of which is incorporated herein by reference.

### BACKGROUND

### 1. Technical Field

The present disclosure relates to a semiconductor light-emitting apparatus.

### 2. Description of the Related Art

A semiconductor light-emitting apparatus in which a semiconductor light-emitting element bonded on a package substrate is sealed by a resin is known. For example, a technology for improving light extraction efficiency by forming the sealing resin in an upward convex dome shape has been proposed (see, for example, JP2020-17427).

To form a sealing member in a dome shape, it is necessary to increase the thickness of the sealing member located above the semiconductor light-emitting element. Increasing the amount of the sealing member filling the dome increases a distortion caused by a difference in the material between the sealing member and the package substrate with the result that the sealing member is easily exfoliated or cracked.

### SUMMARY

The present disclosure addresses the issue described above, and a purpose thereof is to provide a technology for improving the light extraction efficiency and the reliability of a semiconductor light-emitting apparatus.

A semiconductor light-emitting apparatus according to an embodiment of the present disclosure includes: a package substrate; a semiconductor light-emitting element including an anode electrode and a cathode electrode bonded to the package substrate, a semiconductor layer on the anode electrode and the cathode electrode, and a translucent substrate on the semiconductor layer; and a covering member that is in contact with an upper surface of the translucent substrate, has a dome shape that is convex upward, has translucency at an emission wavelength of the semiconductor light-emitting element, has a lower refractive index than the translucent substrate, and that is not in contact with the package substrate.

### BRIEF DESCRIPTION OF THE DRAWINGS

FIG. 1 is a cross-sectional view schematically showing a configuration of a semiconductor light-emitting apparatus according to the first embodiment.

FIG. 2 is a top view schematically showing a configuration of a semiconductor light-emitting apparatus according to the first embodiment.

FIG. 3 is a cross-sectional view schematically showing a configuration of a semiconductor light-emitting apparatus according to the second embodiment.

FIG. 4 is a cross-sectional view schematically showing a configuration of a semiconductor light-emitting apparatus according to the third embodiment.

FIG. 5 is a top view schematically showing a configuration of the semiconductor light-emitting apparatus according to the third embodiment.

FIG. 6 is a cross-sectional view schematically showing a configuration of a semiconductor light-emitting apparatus according to the fourth embodiment.

FIG. 7 is a cross-sectional view schematically showing a configuration of a semiconductor light-emitting apparatus according to the fourth embodiment.

### DETAILED DESCRIPTION

The invention will now be described by reference to the preferred embodiments. This does not intend to limit the scope of the present invention, but to exemplify the invention.

A description will be given of an embodiment to practice the present disclosure with reference to the drawings. The numerals are used in the description to denote the same elements and a duplicate description is omitted as appropriate. To facilitate the understanding, the relative dimensions of the constituting elements in the drawings do not necessarily mirror the relative dimensions in the light-emitting element.

According to the present disclosure, the light extraction efficiency and the reliability of a semiconductor light-emitting apparatus can be improved.

### First Embodiment

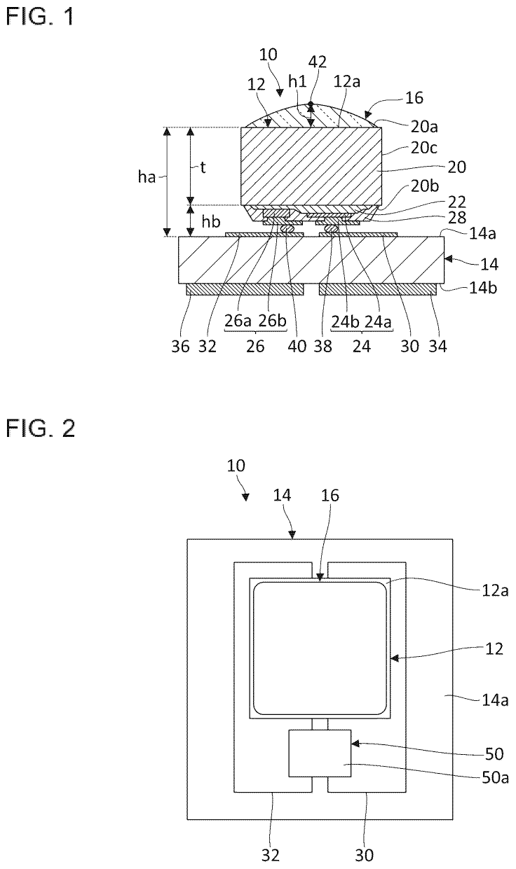

FIG. 1 is a cross-sectional view schematically showing a configuration of a semiconductor light-emitting apparatus 10 according to the first embodiment. The semiconductor light-emitting apparatus 10 includes a semiconductor light-emitting element 12, a package substrate 14, and a covering member 16.

The semiconductor light-emitting element 12 is a semiconductor light-emitting element configured to emit ultraviolet light having a central wavelength λ of approximately equal to or less than 360 nm. To output ultraviolet light having such a wavelength, an aluminum gallium nitride (AlGaN)-based semiconductor material having a band gap approximately equal to or more than 3.4 eV is used. In the embodiment, a deep ultraviolet-light emitting diode (DUV-LED) chip configured to emit deep ultraviolet light having a central wavelength λ of about 240 nm to 320 nm will be highlighted.

The semiconductor light-emitting element 12 includes a translucent substrate 20, a semiconductor layer 22, an anode electrode 24, a cathode electrode 26, and a protective layer 28.

The translucent substrate 20 is made of a material having translucency for the ultraviolet light emitted by the semiconductor light-emitting element 12. The light emitted by the semiconductor layer 22 is output outside the semiconductor light-emitting element 12 from the translucent substrate 20. The translucent substrate 20 is made of, for example, sapphire (Al₂O₃). The translucent substrate 20 includes an upper surface 20a, a lower surface 20b, and a side surface 20c. The upper surface 20a and the lower surface 20b has, for example, a rectangular shape. The size of the upper surface 20a and the lower surface 20b is not limited to a particular size. For example, the upper surface 20a and the lower surface 20b are 1 mm by 1 mm in size. The thickness t of the translucent substrate 20 from the upper surface 20a to the lower surface 20b is, for example, equal to or more than 100 μm, equal to or more than 200 μm, or equal to or more than 300 μm and is, for example, equal to or less than 1000 μm, equal to or less than 700 μm, or equal to or less than 500 μm.

The semiconductor layer 22 is provided below the translucent substrate 20 and is provided on the lower surface 20b of the translucent substrate 20. The semiconductor layer 22 includes, for example, an n-type semiconductor layer, an active layer, and a p-type semiconductor layer. The semiconductor layer 22 is made of an AlGaN-based semiconductor material. The AlGaN-based semiconductor material can be represented by a composition In_{1-x-y}AlₓGa_{y}N (0<x+y≤1, 0<x<1, 0<y<1). The semiconductor layer 22 is covered by the protective layer 28.

The anode electrode 24 includes a first contact electrode 24a and a first pad electrode 24b. The first contact electrode 24a is an internal electrode in contact with the semiconductor layer 22 and is in contact with the p-type semiconductor layer included in the semiconductor layer 22. The first contact electrode 24a is comprised of, for example, a metal layer made of Rh, etc. The first contact electrode 24a is covered by the protective layer 28. The first pad electrode 24b is an external electrode exposed outside the protective layer 28 and is electrically connected to the first contact electrode 24a via an opening provided in the protective layer 28. The first pad electrode 24b is comprised of a metal layer made of Ni/Au, etc.

The cathode electrode 26 includes a second contact electrode 26a and a second pad electrode 26b. The second contact electrode 26a is an internal electrode in contact with the semiconductor layer 22 and is in contact with the n-type semiconductor layer included in the semiconductor layer 22. The second contact electrode 26a is comprised of, for example, a metal layer made of Ti/Al, etc. The second contact electrode 26a is covered by the protective layer 28. The second pad electrode 26b is an external electrode exposed outside the protective layer 28 and is electrically connected to the second contact electrode 26a via an opening provided in the protective layer 28. The second pad electrode 26b is comprised of a metal layer made of Ni/Au, etc.

The protective layer 28 covers the semiconductor layer 22, the first contact electrode 24a, and the second contact electrode 26a. The protective layer 28 is made of a dielectric material such as oxide and nitride and is made of, for example, silicon oxide (SiO₂), aluminum oxide (Al₂O₃), silicon nitride (SiN), etc. The protective layer 28 may be comprised of a stack of a plurality of protective layers made of different materials.

The package substrate 14 has a flat plate shape, and has a bonding surface 14a and a back surface 14b. The package substrate 14 includes a first bonding electrode 30 and a second bonding electrode 32 provided on the bonding surface 14a. The package substrate 14 includes a first mounting electrode 34 and a second mounting electrode 36 provided on the back surface 14b. The first bonding electrode 30 is electrically connected to the first mounting electrode 34 inside the package substrate 14. The second bonding electrode 32 is electrically connected to the second mounting electrode 36 inside the package substrate 14. The package substrate 14 is made of, for example, an inorganic material, and is made of a ceramic material such as alumina (Al₂O₃), aluminum nitride (AlN), silicon nitride (SiN), and silicon carbide (SiC).

The semiconductor light-emitting element 12 is flip-chip bonded on the package substrate 14. The semiconductor light-emitting element 12 is bonded to the first bonding electrode 30 and the second bonding electrode 32. The semiconductor light-emitting element 12 is bonded to the package substrate 14 via a first bonding part 38 and a second bonding part 40. The first bonding part 38 is provided between the anode electrode 24 (the first pad electrode 24b) and the first bonding electrode 30 to connect the anode electrode 24 and the first bonding electrode 30 electrically. The second bonding part 40 is provided between the cathode electrode 26 (the second pad electrode 26b) and the second bonding electrode 32 to connect the cathode electrode 26 and the second bonding electrode 32 electrically.

The first bonding part 38 and the second bonding part 40 are, for example, stud bumps. The first bonding part 38 and the second bonding part 40 are formed by, for example, melting the tip of a metal wire made of Au, etc. to form a ball and pressing the ball against the first bonding electrode 30 and the second bonding electrode 32, respectively. The first bonding part 38 and the second bonding part 40 formed on the first bonding electrode 30 and the second bonding electrode 32 are respectively bonded to the anode electrode 24 (the first pad electrode 24b) and the cathode electrode 26 (the second pad electrode 26b) by, for example, ultrasonic bonding.

In a state where the semiconductor light-emitting element 12 is bonded to the package substrate 14, the height hb from the package substrate 14 (the bonding surface 14a) to the lower surface 20b of the translucent substrate 20 is, for example, smaller than the thickness t of the translucent substrate 20 and is, for example, smaller than half t/2 the thickness of the translucent substrate 20. The height hb from the package substrate 14 to the lower surface 20b of the translucent substrate 20 is, for example, equal to or less than 200 μm, equal to or less than 100 μm, equal to or less than 50 μm, or equal to or less than 30 μm. The height hb from the package substrate 14 to the lower surface 20b of the translucent substrate 20 is, for example, equal to or more than 10 μm, equal to or more than 15 μm, equal to or more than 20 μm, or equal to or more than 25 μm.

In a state where the semiconductor light-emitting element 12 is bonded to the package substrate 14, the height ha from the package substrate 14 (the bonding surface 14a) to the upper surface 12a of the semiconductor light-emitting element 12 (the upper surface 20a of the translucent substrate 20) is, for example, equal to or more than 100 μm, equal to or more than 200 μm, equal to or more than 300 μm, or equal to or more than 400 μm. The height ha from the package substrate 14 to the upper surface 12a of the semiconductor light-emitting element 12 is, for example, equal to or less than 1000 μm, equal to or less than 700 μm, equal to or less than 600 μm, or equal to or less than 500 μm.

The covering member 16 covers the upper surface 12a of the semiconductor light-emitting element 12 on the package substrate 14. The covering member 16 is in contact with the upper surface 20a of the translucent substrate 20. The covering member 16 is not in contact with the side surface 20c of the translucent substrate 20. The covering member 16 is provided in isolation from the package substrate 14 and is not in contact with the package substrate 14. The covering member 16 is made of a material having translucency at the emission wavelength of the semiconductor light-emitting element 12. The covering member 16 has an internal transmittance of equal to or more than 50%, and, preferably equal to or more than 70%, equal to or more than 80%, or equal to or more than 90% at the peak emission wavelength of the semiconductor light-emitting element 12. The covering member 16 is made of a material having a lower refractive index than the translucent substrate 20. The covering member 16 is made of, for example, a silicone resin or a fluororesin. The covering member 16 may be made of an inorganic material such as quartz or a glass material instead of a resin. The covering member 16 is configured not to contain, for example, a phosphor.

The covering member 16 has, for example, a lens shape or a dome shape that is convex upward. The height h1 from the upper surface 12a of the semiconductor light-emitting element 12 to an apex portion 42 of the covering member 16 is, for example, equal to or more than 50 μm, equal to or more than 100 μm, equal to or more than 200 μm, or equal to or more than 300 μm. The height h1 from the upper surface 12a of the semiconductor light-emitting element 12 to the apex portion 42 of the covering member 16 is, for example, equal to or less than 1000 μm, equal to or less than 800 μm, equal to or less than 600 μm, or equal to or less than 500 μm. By providing the covering member 16 having translucency and a low refractive index on the upper surface 20a of the translucent substrate 20, the efficiency of extracting light output outside from the translucent substrate 20 can be improved compared to a case where the covering member 16 is not provided.

FIG. 2 is a top view schematically showing a configuration of the semiconductor light-emitting apparatus 10 according to the first embodiment. The semiconductor light-emitting apparatus 10 further includes a protective element 50. The protective element 50 is a diode for protecting the semiconductor light-emitting element 12 from a surge current or static electricity and is, for example, a Zener diode. The protective element 50 is bonded to the bonding surface 14a of the package substrate 14. The protective element 50 is bonded to the first bonding electrode 30 and the second bonding electrode 32 and is connected in parallel with the semiconductor light-emitting element 12.

In the example of FIG. 2, the upper surface 12a of the semiconductor light-emitting element 12 is rectangular and has four sides and four corner portions. The upper surface 12a of the semiconductor light-emitting element 12 may not be rectangular and may have a polygonal shape such as a triangle, hexagon, or octagon shape different from a quadrilateral shape. The protective element 50 is arranged in close proximity to one side of the semiconductor light-emitting element 12.

The covering member 16 is provided over the entire upper surface 12a of the semiconductor light-emitting element 12 (that is, the upper surface 20a of the translucent substrate 20). The range in which the covering member 16 is provided is equal to or more than 80%, equal to or more than 85%, equal to or more than 90%, or equal to or more than 95% of the area of the upper surface 12a of the semiconductor light-emitting element 12. In the example of FIG. 2, the covering member 16 is not provided on an upper surface 50a of the protective element 50. An additional covering member may be provided on the upper surface 50a of the protective element 50. The additional covering member provided on the upper surface 50a of the protective element 50 may be integrally formed with the covering member 16 provided on the upper surface 12a of the semiconductor light-emitting element 12 or may be formed separate from the covering member 16.

According to this embodiment, the efficiency of extracting light output outside from the semiconductor light-emitting element 12 can be improved compared to a case where the covering member 16 is not provided, by providing the covering member 16 having translucency and a low refractive index on the upper surface 12a of the semiconductor light-emitting element 12. The light extraction efficiency of the semiconductor light-emitting apparatus 10 can be improved by, for example, about 108-30% compared to a case where the covering member 16 is not provided.

According to this embodiment, the amount of the covering member 16 used can be reduced by providing the covering member 16 only on the upper surface 12a of the semiconductor light-emitting element 12. Further, the covering member 16 is provided in isolation from the package substrate 14 so that the stress applied to the covering member 16 can be reduced. As a result, the occurrence of exfoliation and cracks of the covering member 16 can be suppressed, and the reliability of the semiconductor light-emitting apparatus 10 can be improved.

### Second Embodiment

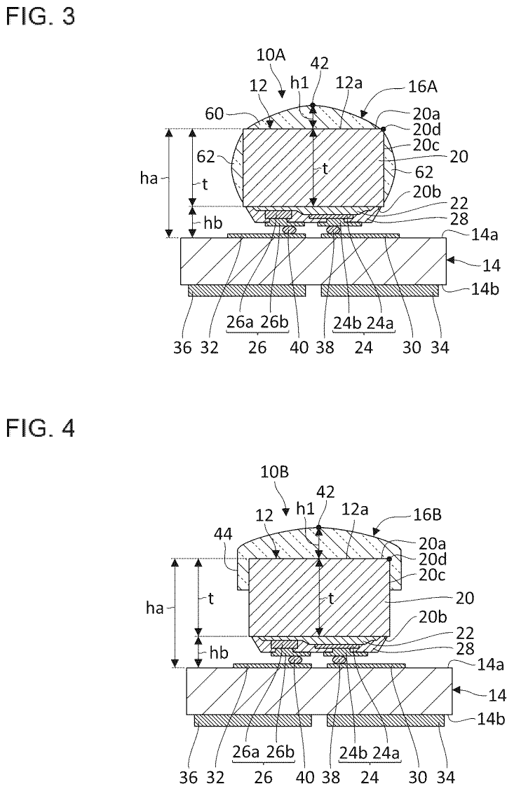

FIG. 3 is a cross-sectional view schematically showing a configuration of a semiconductor light-emitting apparatus 10A according to the second embodiment. The second embodiment differs from the first embodiment in that a covering member 16A includes an upper surface covering portion 60 in contact with the upper surface 20a of the translucent substrate 20 and a side surface covering portion 62 in contact with the side surface 20c of the translucent substrate 20. The following description of the second embodiment highlights the difference from the first embodiment. A description of common features is omitted as appropriate.

The semiconductor light-emitting apparatus 10A includes a semiconductor light-emitting element 12, a package substrate 14, and a covering member 16A. The semiconductor light-emitting apparatus 10A may further include the protective element 50 shown in FIG. 2. The semiconductor light-emitting element 12, the package substrate 14, and the protective element 50 can be configured in the same manner as in the first embodiment.

The covering member 16A includes an upper surface covering portion 60 and a side surface covering portion 62. The upper surface covering portion 60 is provided on the upper surface 20a of the translucent substrate 20 and is in contact with the upper surface 20a of the translucent substrate 20. The upper surface covering portion 60 is not in contact with the side surface 20c of the translucent substrate 20. The upper surface covering portion 60 has a dome shape that is convex upward. The upper surface covering portion 60 can be configured in the same manner as the covering member 16 according to the first embodiment.

The side surface covering portion 62 is provided on the side surface 20c of the translucent substrate 20 and is in contact with the side surface 20c of the translucent substrate 20. The side surface covering portion 62 has, for example, a dome shape that is convex sideward. The side surface covering portion 62 is provided on at least one of a plurality of (e.g., four) side surfaces 20c of the translucent substrate 20. The side surface covering portion 62 may be provided on each of the plurality of (e.g., four) side surfaces 20c of the translucent substrate 20. The side surface covering portion 62 is provided in isolation from the package substrate 14 and is not in contact with the package substrate 14. The side surface covering portion 62 is made of the same material as the covering member 16 according to the first embodiment. The side surface covering portion 62 may be made of the same material as the upper surface covering portion 60 or may be made of a material different from that of the upper surface covering portion 60.

The covering member 16A is formed not to substantially cover a corner portion 20d between the upper surface 20a and the side surface 20c of the translucent substrate 20. In other words, the covering thickness of the covering member 16A at the corner portion 20d is smaller than the covering thickness of the covering member 16A at the other portions (the top surface 20a or the side surface 20c). For example, the covering member 16A is formed such that there is a gap between the upper surface covering portion 60 and the side surface covering portion 62 and is formed such that the upper surface covering portion 60 and the side surface covering portion 62 are formed are isolated. The upper surface covering portion 60 and the side surface covering portion 62 may be formed such that they are in contact with each other and the covering thickness of the covering member 16A at the corner portion 20d is very small.

According to this embodiment, the covering member 16A having translucency and a low refractive index is provided on the upper surface 20a and the side surface 20c of the translucent substrate 20 so that the efficiency of extracting light output outside from the semiconductor light-emitting element 12 can be further improved. According to this embodiment, too, the covering member 16A is provided in isolation from the package substrate 14 so that the stress applied to the covering member 16A can be reduced. As a result, the occurrence of exfoliation and cracks of the covering member 16A can be suppressed, and the reliability of the semiconductor light-emitting apparatus 10A can be improved.

### Third Embodiment

FIG. 4 is a cross-sectional view schematically showing a configuration of a semiconductor light-emitting apparatus 10B according to the third embodiment. The third embodiment differs from the embodiments described above in that the covering member 16B is in contact with both the upper surface 20a and the side surface 20c of the translucent substrate 20. The following description of the third embodiment highlights the difference from the first embodiment. A description of common features is omitted as appropriate.

The semiconductor light-emitting apparatus 10B includes a semiconductor light-emitting element 12, a package substrate 14, and a covering member 16B. The semiconductor light-emitting apparatus 10B may further include the protective element 50 shown in FIG. 2. The semiconductor light-emitting element 12, the package substrate 14, and the protective element 50 can be configured in the same manner as in the first embodiment.

The covering member 16B is provided to be in contact with both the upper surface 20a and the side surface 20c of the translucent substrate 20. The covering member 16B has a dome shape that is convex upward. The covering member 16B covers the corner portion 20d between the upper surface 20a and the side surface 20c of the translucent substrate 20. The covering thickness of the covering member 16B at the corner portion 20d may be equal to or more than the covering thickness of the covering member 16B at the side surface 20c. The covering member 16B is formed such that a side surface 44 of the covering member 16B is flat rather than dome-shaped. In other words, the side surface 44 of the covering member 16B is substantially parallel to the side surface 20c of the translucent substrate 20, and the covering thickness of the covering member 16B at the side surface 20c is substantially constant. The covering member 16B can be made of the same material as in the first embodiment.

The height h1 from the upper surface 12a of the semiconductor light-emitting element 12 to the apex portion 42 of the covering member 16 is, for example, equal to or more than 100 μm, equal to or more than 200 μm, or equal to or more than 300 μm. The height h1 from the upper surface 12a of the semiconductor light-emitting element 12 to the apex portion 42 of the covering member 16 is, for example, equal to or less than 1000 μm, equal to or less than 800 μm, or equal to or less than 500 μm.

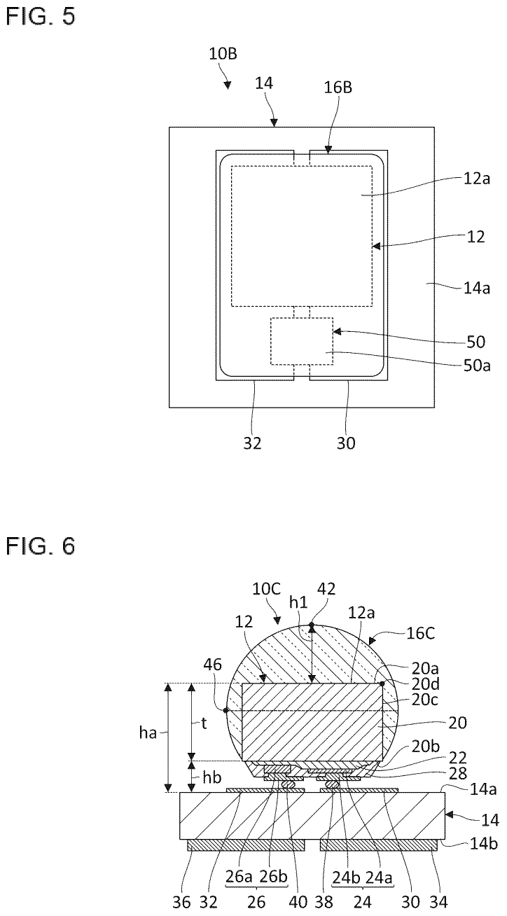

FIG. 5 is a top view schematically showing a configuration of the semiconductor light-emitting apparatus 10B according to the third embodiment. In the example of FIG. 5, too, the upper surface 12a of the semiconductor light-emitting element 12 is rectangular and has four sides and four corner portions. The upper surface 12a of the semiconductor light-emitting element 12 may not be rectangular and may have a polygonal shape such as a triangle, hexagon, or octagon shape different from a quadrilateral shape. The protective element 50 is arranged in close proximity to one side of the semiconductor light-emitting element 12.

In the example of FIG. 5, the covering member 16B is also provided on the upper surface 50a of the protective element 50, and the covering member 16B is in contact with the upper surface 50a of the protective element 50. The covering member 16B may be in contact with the side surface of the protective element 50 or may not be in contact with the side surface of the protective element 50. In the example of FIG. 5, the covering member 16B is integrally formed across the upper surface 12a of the semiconductor light-emitting element 12 and the upper surface 50a of the protective element 50. This makes it possible to extend the range in which the covering member 16B is provided and makes it easy to increase the height h1 of the apex portion 42 of the covering member 16B. In a variation, the covering member 16B may be provided in isolation from the upper surface 50a of the protective element 50 and may not be in contact with the upper surface 50a of the protective element 50.

The covering member 16B is provided over a range more extensive than the upper surface 12a of the semiconductor light-emitting element 12 (that is, the upper surface 20a of the translucent substrate 20). The range in which the covering member 16B is provided is, for example, equal to or more than 105%, equal to or more than 110%, equal to or more than 1158, or equal to or more than 120% of the area of the upper surface 20a of the translucent substrate 20. The range in which the covering member 16B is provided is, for example, equal to or less than 200%, equal to or less than 150%, equal to or less than 140%, or equal to or less than 130% of the area of the upper surface 20a of the translucent substrate 20.

According to this embodiment, the covering member 16B is provided over a range more extensive than the upper surface 20a of the translucent substrate 20 so that it is easy to increase the height h1 of the covering member 16B and to increase the curvature of the surface of the covering member 16B. This can further improve the light extraction efficiency of the semiconductor light-emitting apparatus 10B. According to this embodiment, too, the covering member 16B is provided in isolation from the package substrate 14 so that the stress applied to the covering member 16B can be reduced. As a result, the occurrence of exfoliation and cracks of the covering member 16B can be suppressed, and the reliability of the semiconductor light-emitting apparatus 10A can be improved.

### Fourth Embodiment

FIG. 6 is a cross-sectional view schematically showing a configuration of a semiconductor light-emitting apparatus 10C according to the fourth embodiment. The fourth embodiment differs from the embodiments described above in that a covering member 16C is formed in a spherical shape. The following description of the fourth embodiment highlights the difference from the third embodiment. A description of common features is omitted as appropriate.

The semiconductor light-emitting apparatus 10C includes a semiconductor light-emitting element 12, a package substrate 14, and a covering member 16C. The semiconductor light-emitting apparatus 10C may further include the protective element 50 shown in FIG. 2 or FIG. 5. The semiconductor light-emitting element 12, the package substrate 14, and the protective element 50 can be configured in the same manner as in the first embodiment.

The covering member 16C is provided to be in contact with both the upper surface 20a and the side surface 20c of the translucent substrate 20. The covering member 16C has a dome shape that is convex upward and a dome shape that is convex sideward. The covering member 16C has a spherical shape or a ball shape as a whole. The covering member 16C is formed to cover the corner portion 20d of the translucent substrate 20. The covering member 16C is formed such that a portion 46 where the width (the size perpendicular to the height direction) of the covering member 16C is maximized is located between the upper surface 20a and the lower surface 20b of the translucent substrate 20. The covering member 16C can be made of the same material as in the first embodiment.

According to this embodiment, the curvature of the surface of the covering member 16C can be further increased and the light extraction efficiency of the semiconductor light-emitting apparatus 10C can be further improved as compared to the second embodiment shown in FIG. 3.

### Fifth Embodiment

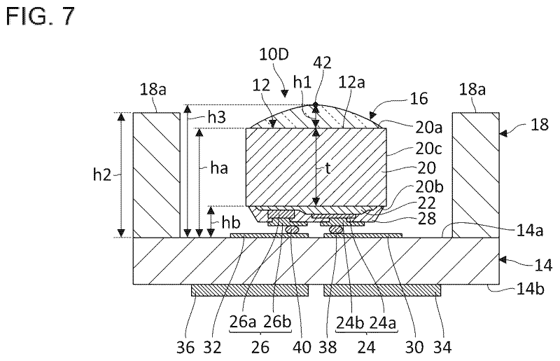

FIG. 7 is a cross-sectional view schematically showing a configuration of a semiconductor light-emitting apparatus 10D according to the fourth embodiment. The semiconductor light-emitting apparatus 10D differs from the embodiments described above in that it further includes a frame body 18 provided around the semiconductor light-emitting element 12 on the package substrate 14. The following description of the fifth embodiment highlights the difference from the first embodiment. A description of common features is omitted as appropriate.

The semiconductor light-emitting apparatus 10D includes a semiconductor light-emitting element 12, a package substrate 14, a covering member 16A, and a frame body 18. The semiconductor light-emitting apparatus 10D may further include the protective element 50 shown in FIG. 2. The semiconductor light-emitting element 12, the package substrate 14, the covering member 16, and the protective element 50 can be configured in the same manner as in the first embodiment.

The frame body 18 is provided around the semiconductor light-emitting element 12 on the package substrate 14. The frame body 18 is provided, for example, along the outer circumference of the package substrate 14 and over the entire circumference of the package substrate 14. The frame body 18 may be provided in isolation from the outer circumference of the package substrate 14 or may be provided at a position displaced inward from the outer circumference of the package substrate 14. The frame body 18 is made of, for example, the same material as that of the package substrate 14, and is integrally molded with the package substrate 14. The frame body 18 may be made of a material different from that of the package substrate 14. The frame body 18 may be molded as a body separate from the package substrate 14, or may be bonded to the bonding surface 14a of the package substrate 14 by any bonding material.

The frame body 18 has an upper surface 18a. The upper surface 18a of the frame body 18 is, for example, a flat surface. The height h2 of the upper surface 18a of the frame body 18 is, for example, equal to or more than 200 μm, equal to or more than 300 μm, equal to or more than 400 μm, or equal to or more than 500 μm. The height h2 of the upper surface 18a of the frame body 18 is, for example, equal to or less than 1500 μm, equal to or less than 1200 μm, equal to or less than 1000 μm, or equal to or less than 800 μm.

The height h2 of the upper surface 18a of the frame body 18 is, for example, larger than the height ha of the upper surface 12a of the semiconductor light-emitting element 12. The height h2 of the upper surface 18a of the frame body 18 is, for example, larger than the height hb of the lower surface 20b of the translucent substrate 20 and larger than the height ha of the upper surface 20a of the translucent substrate 20. The height h2 of the upper surface 18a of the frame body 18 is, for example, equal to or less than the height h3 (h1+ha) of the apex portion 42 of the covering member 16. The height h2 of the upper surface 18a of the frame body 18 may be larger than the height h3 of the apex portion 42 of the covering member 16. The height h2 of the upper surface 18a of the frame body 18 may be smaller than the height ha of the upper surface 12a of the semiconductor light-emitting element 12. The height h2 of the upper surface 18a of the frame body 18 may be smaller than the height hb of the lower surface 20b of the translucent substrate 20.

The covering member 16 is provided in isolation from the frame body 18 and is not in contact with the frame body 18.

According to this embodiment, the covering member 16 is provided in isolation from the frame body 18 even when the frame body 18 is provided on the package substrate 14 so that the stress applied to the covering member 16 can be reduced as compared with a case where the covering member 16 is in contact with the frame body 18. As a result, the occurrence of exfoliation and cracks of the covering member 16 can be suppressed, and the reliability of the semiconductor light-emitting apparatus 10 can be improved.

The frame body 18 according to the fifth embodiment may be applied not only to the first embodiment but also to the second embodiment, third embodiment or fourth embodiment.

Given above is a description of the present disclosure based on the embodiment. The present disclosure is not restricted by the embodiment described above, and it will be understood by those skilled in the art that various design changes are possible and various modifications are possible and that such modifications are also within the scope of the present disclosure.

Some aspects of the present disclosure will be described.

The first aspect of the present disclosure relates to a semiconductor light-emitting apparatus including: a package substrate; a semiconductor light-emitting element including an anode electrode and a cathode electrode bonded to the package substrate, a semiconductor layer on the anode electrode and the cathode electrode, and a translucent substrate on the semiconductor layer; and a covering member that is in contact with an upper surface of the translucent substrate, has a dome shape that is convex upward, has translucency at an emission wavelength of the semiconductor light-emitting element, has a lower refractive index than the translucent substrate, and that is not in contact with the package substrate. According to the first aspect, it is possible to improve the light extraction efficiency of the semiconductor light-emitting apparatus by providing a covering member having translucency and a low refractive index on the upper surface of the translucent substrate. The covering member is provided in isolation from the package substrate so that the stress applied to the covering member resulting from a contact of the covering member with other members can be reduced, and the occurrence of exfoliation and cracks of the covering member can be suppressed. This improves the reliability of the semiconductor light-emitting apparatus.

The second aspect of the present disclosure relates to the semiconductor light-emitting apparatus according to the first aspect, wherein the covering member is in contact with a side surface of the translucent substrate. According to the second aspect, the efficiency of extracting light from the side surface of the translucent substrate can be improved by bringing the covering member having a low refractive index into contact also with the side surface of the translucent substrate.

The third aspect of the present disclosure relates to the semiconductor light-emitting apparatus according to the first aspect or the second aspect, further including: a protective element bonded on the package substrate, wherein the covering member is not in contact with the protective element. According to the third aspect, the influence of the stress applied to the covering member resulting from a contact of the covering member with the protective element can be eliminated, and the occurrence of exfoliation and cracks of the covering member can be suppressed. This improves the reliability of the semiconductor light-emitting apparatus.

The fourth aspect of the present disclosure relates to the semiconductor light-emitting apparatus according to the first aspect or the second aspect, further including: a protective element bonded on the package substrate, wherein the covering member is in contact with an upper surface of the protective element. According to the fourth aspect, the range in which the covering member is formed can be extended by bringing the covering member into contact with the protective element. This increases the light extraction efficiency of the semiconductor light-emitting apparatus.

The fifth aspect of the present disclosure relates to the semiconductor light-emitting apparatus according to any one of the first to fourth aspects, further including: a frame body provided around the semiconductor light-emitting element on the package substrate, wherein the covering member is not in contact with the frame body. According to the fifth aspect, the influence of the stress applied to the covering member resulting from a contact of the covering member with the frame body can be eliminated, and the occurrence of exfoliation and cracks of the covering member can be suppressed in the case the frame body is provided on the package substrate. This improves the reliability of the semiconductor light-emitting apparatus.

What is claimed is:

1. A semiconductor light-emitting apparatus comprising:
a package substrate;
a semiconductor light-emitting element including an anode electrode and a cathode electrode bonded to the package substrate, a semiconductor layer on the anode electrode and the cathode electrode, and a translucent substrate on the semiconductor layer; and
a covering member that is in contact with an upper surface of the translucent substrate, has a dome shape that is convex upward, has translucency at an emission wavelength of the semiconductor light-emitting element, has a lower refractive index than the translucent substrate, and that is not in contact with the package substrate.

2. The semiconductor light-emitting apparatus according to claim 1,
wherein the covering member is in contact with a side surface of the translucent substrate.

3. The semiconductor light-emitting apparatus according to claim 1, further comprising:
a protective element bonded on the package substrate,
wherein the covering member is not in contact with the protective element.

4. The semiconductor light-emitting apparatus according to claim 1, further comprising:
a protective element bonded on the package substrate,
wherein the covering member is in contact with an upper surface of the protective element.

5. The semiconductor light-emitting apparatus according to claim 1, further comprising:
a frame body provided around the semiconductor light-emitting element on the package substrate,
wherein the covering member is not in contact with the frame body.
